(19) United States
(12) Patent Application Publication
(10) Pub. No.: US 2015/0027522 A1
(43) Pub. Date: Jan. 29, 2015

(54) ALL-BLACK-CONTACT SOLAR CELL AND FABRICATION METHOD

(71) Applicants: Thomas Mueller, Singapore (SG); Armin Gerhard Aberle, Singapore (SG)

(72) Inventors: Thomas Mueller, Singapore (SG); Armin Gerhard Aberle, Singapore (SG)

(73) Assignee: TRINA SOLAR ENERGY DEVELOPMENT PTE LTD, SG (SG)

(21) Appl. No.: 14/241,762

(22) PCT Filed: Nov. 16, 2011
(86) PCT No.: PCT/SG2011/000406

§ 371 Date: Sep. 10, 2014

(51) Int. Cl. H01L 31/02; H01L 31/0236; H01L 31/0216; H01L 31/0224; H01L 31/18

(52) U.S. Cl. CPC H01L 31/02008; H01L 31/022441; H01L 31/1868; H01L 31/02168; H01L 31/02363
USPC 136/256; 438/98; 438/72

(57) ABSTRACT

A method of fabricating an all-back-contact (ABC) solar cell is disclosed. A doped layer of a first polarity (102) is formed on a rear side of a wafer (100). A first masking structure (106, 110) is formed on the doped layer of the first polarity. Portions of the first masking structure (106, 110) are removed using a first laser ablation process. Doped regions of a second polarity (118, 135, 137) are formed in areas where the first masking structure has been removed. Contact bars (134, 136) are formed by screen printing and firing such that each contact bar is in contact with one of the doped regions (135, 137).

### TECHNICAL FIELD

The present invention relates broadly to a method of fabricating an all-back-contact (ABC) solar cell, and to an ABC solar cell.

### BACKGROUND

All-back-contact (ABC) silicon wafer solar cells have the potential of achieving a high energy conversion efficiency with a cost-effective and industrially feasible fabrication process. The cells are sometimes referred to as interdigitated back contact (IBC) cells, because of the interpenetrating contacts (metal fingers) of opposite polarity on the rear of the cell. ABC cells have several advantages over conventional silicon wafer solar cells, which have contacts on both surfaces, whereby the front contact is a metal grid consisting of parallel fingers and several busbars connecting the metal fingers. The advantages of ABC cells include improved photo-generation of carriers due to the elimination of the optical front-metal grid shading and improved blue response since heavy front-surface doping to reduce the front contact resistance is not required due to the shifting of the front contacts to the rear of the cell. In addition, ABC cells have a uniform and thus more favourable appearance in modules, due to the absence of the front metal grid on the front surface.

Wafers with high carrier lifetime and good front surface passivation are typically required for ABC solar cells, because photo-generated carriers must all travel to the rear surface where the charge-separating p-n junction is located. As a result, n-type wafers are typically used for ABC solar cells due to their higher carrier lifetime compared to p-type wafers.

ABC silicon wafer solar cell architectures have the potential for conversion efficiencies of well over 24% due to the high-lifetime wafers, eliminated optical shading at the front, improved blue response and lower surface recombination rates by good surface passivation possibilities. However, current fabrication methods and cost considerations have prevented the ABC cell from being cost-effective for application in conventional low-cost industrial solar cell manufacturing lines. The main issues during the manufacturing are the patterning of the rear side to establish the interdigitated p-doped and n-doped regions including the use of photoresist or printed resist, processing, mask alignments, and the use of metal deposition providing a low contact resistance, such as thermal or electron-beam evaporation or sputtering. As these processes mainly originate from the semiconductor industry, the processing must typically be carried out in a cleanroom environment.

For industry-size silicon wafers (area>100 cm²), the use of industrially viable screen-printing techniques does so far not seem to provide a sufficiently accurate alignment to the interdigitated diffused silicon regions of ABC cells. The reports available to date are limited to small solar cell areas of less than 14 cm² [Romijn et al, “Back-Contacted Cells for Pilot Line Processing with >19% Efficiency”, Future Photovoltaics, August 2011]. It seems that no solution has yet been found for an industrial low-cost screen-printing process for ABC cells with high production yield.

A need therefore exists to provide a method of fabricating an ABC solar cell and an ABC solar cell that seek to address at least one of the above mentioned problems.

### SUMMARY

A method of fabricating an all-back-contact (ABC) solar cell is provided. A doped layer of a first polarity is formed on a rear side of a wafer. A first masking structure is formed on the doped layer of the first polarity. Portions of the first masking structure are removed using a first laser ablation process. Doped regions of a second polarity are formed in areas where the first masking structure has been removed. Contact bars are formed by screen printing and firing such that each contact bar is in contact with one of the doped regions.

Preferably, a first alignment process is applied for the first laser ablation process; and a second corresponding alignment process is applied for the screen printing of the contact bars. Forming the doped region of the second polarity can include applying a caustic etch to expose deeper lying regions in the openings formed in the first masking structure by the first laser ablation process, and doping the exposed portions of the wafer. A dielectric passivation structure can be formed over the entire rear surface of the wafer.

Furthermore, forming the contact bars can be by screen printing a fritted metal paste on the dielectric passivation structure and firing the fritted paste to form at least respective seed layers of the contact bars. The fritted metal paste is screen printed such that the contact bars are in contact with the silicon wafer after the firing process. Build-up of the contact bars from the seed layers can be by using screen printing or ink-jet printing. Forming the contact bars by screen printing can comprise forming openings in the dielectric passivation structure and screen printing a non-fritted metal paste to form the contact bars. The openings in the dielectric passivation layer are formed by a second laser ablation process.

Further preferably, forming the doped layer of the first polarity can include using diffusion doping from a solid or gaseous source, or ion implantation. Forming the doped regions of the second polarity can comprise using diffusion doping from a solid or gaseous source, or ion implantation. Additionally, texturing a front surface of the wafer can be performed. A dielectric structure can be formed on a front surface of the wafer. The dielectric structure can have passivation and anti-reflective properties.

There is further provided an all-back-contact (ABC) solar cell formed using any one or more of the methods described above.

Preferably, the solar cell has a dielectric passivation structure over the entire rear surface of the wafer. The solar cell can have a textured front surface of the wafer. A dielectric stack on a front surface of the wafer may be provided. The dielectric stack can have passivation and anti-reflective properties.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIGS. 1 to 8 are schematic drawings illustrating a method of fabricating a full-size screen-printed ABC solar cell according to an example embodiment.

FIG. 9 shows a schematic drawing illustrating an ABC solar cell according to an example embodiment.

FIG. 10 shows a schematic drawing illustrating an ABC solar cell according to another example embodiment.

FIG. 11 shows a schematic drawing illustrating the alignment systems in the laser and printer respectively, according to an example embodiment.

FIGS. 12 a)-i) show microscope images of screen printed metal fingers on laser scribed lines, according to example embodiments.

FIG. 13 shows a flow-chart illustrating a method of fabricating a full-size screen-printed ABC solar cell according to an example embodiment.

### DETAILED DESCRIPTION

The example embodiments described provide a method and a solar cell structure to realise an all-back-contact (ABC) silicon wafer solar cell with screen-printed metal contacts. Laser processing is utilised for patterning of dielectric masking layers (for example silicon oxide or silicon nitride) in one embodiment, enabling localised doping of the exposed silicon surfaces using thermal diffusion processes. Doping can also be realised using ion implantation techniques or laser doping techniques in different embodiments. In one embodiment, p-doped regions and n-doped regions are formed in a surface of the wafer through use of masking, thermal diffusion, laser ablation, and wet-chemical etching techniques. A dielectric stack is advantageously provided at the rear surface of the solar cell to lower the surface recombination rate. Metal contacts are made by screen printing of metal pastes onto the dielectric stack, followed by a fast firing process whereby the metal electrodes penetrate through the dielectric stack to form electrical contact to the underlying heavily doped silicon regions in one embodiment. The front surface of the wafer is preferably textured and coated with a dielectric layer or stack that provides good electronic passivation and antireflection properties.

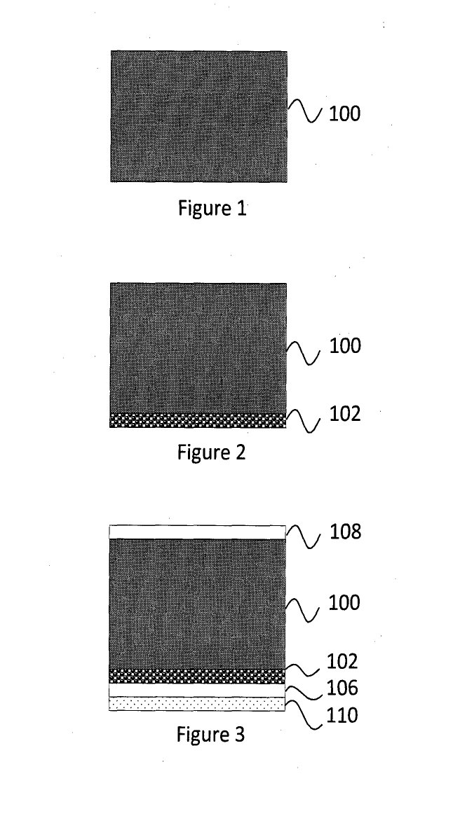

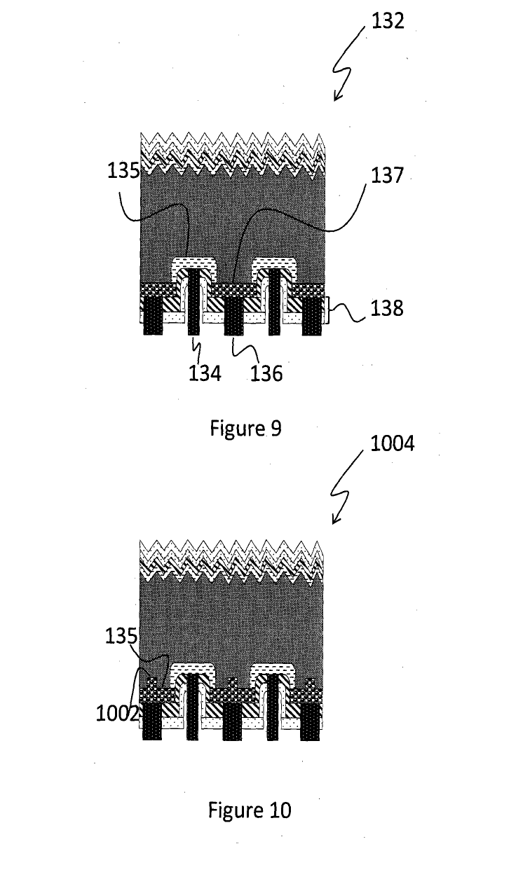

FIGS. 1 to 8 are schematic drawings illustrating a method of fabricating a full-size screen-printed ABC solar cell according to an example embodiment. The solar cell may be, but is not limited to, being formed on a 125 mm×125 mm wafer. A schematic of the final device structure is shown in FIG. 9.

A cross-sectional view of the starting silicon wafer 100 is shown in FIG. 1. The wafer 100 is doped n-type in the resistivity range of 0.5-10 Ohmcm and has a starting thickness of approximately 180 μm and a minority carrier lifetime of greater than 0.5 ms. The wafer 100 undergoes a wet-chemical caustic saw damage etch (SDE), whereby typically at least 15 μm of silicon are removed from each side of the wafer 100. Next, the wafer 100 is cleaned using a wet-chemical cleaning sequence.

Next, a single-sided boron diffusion is performed at the rear 102 of the wafer 100, as shown in FIG. 2. A typical p-n junction depth is around 0.5-2 μm and the sheet resistance is typically in the range of 5-100 Ohm/square. The process is performed in a standard high-temperature tube diffusion furnace in one example embodiment, but other furnace configurations (for example inline diffusion furnace) are also possible. In this embodiment, a liquid boron source (BBr₃) is used to provide the required boron atoms for the diffusion process. The single-sided diffusion of the wafer 100 is realised by placing two wafers into each slot in a carrier, whereby the front surfaces (i.e. the surfaces where no diffusion is desired) of the wafers face each other. After the furnace diffusion process, the boron-rich glassy layer not shown on the wafers is wet-chemically etched away, leaving the p+ layer 102 in this example embodiment.

Next, as shown in FIG. 3, respective silicon oxide layers 106, 108 are thermally grown on both surfaces of the wafer 100. The thickness of the thermal silicon oxide 106, 108 is typically around 2000-3000 Å. On top of the SiO₂ layer 106, a silicon nitride film 110 is then deposited on the rear side or both sides of the wafer 100. The thickness of the silicon nitride 110 can be in the range of 500-1500 Å. The SiN layer 110 serves as protective coating for the subsequent wet-chemical cleaning step in this embodiment.

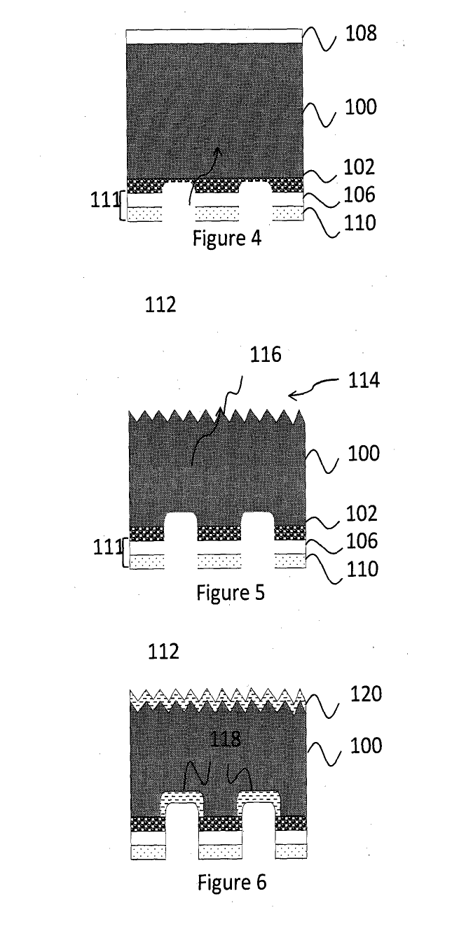

As shown in FIG. 4, the oxide/nitride dielectric stack 111 [106, 110] on the rear is then patterned using laser ablation. The laser ablation creates open lines e.g. 112 approximately 400 to 500 μm wide, with a pitch of the openings of about 2 mm.

Next, as shown in FIG. 5, the openings e.g. 112 in the oxide/nitride dielectric stack 111 are chemically etched in the areas not covered by SiN 110, to remove the laser damage. More particular, a hydrofluoric acid (HF) dip may be used to remove the glassy layer produced by the laser process. A caustic etch (such as concentrated KOH, NaOH or TMAH) is used to etch about 2 to 5 μm of silicon, eliminating the p-n junction. Any boron diffusion that occurred at the edges or the front surface of the wafer is also removed during this etch. Another caustic etch (KOH, NaOH or TMAH) is then used to texture the front surface 114 of the wafer 100, while the p+ diffused layer 102 at the rear surface is protected by the oxide/nitride stack 111. In one embodiment, monocrystalline wafers 100 of the orientation <100> are used, leading to the formation of upright pyramids e.g. 116 with <111> oriented sidewalls. The typical heights of the pyramids e.g. 116 are in the range of 1-10 μm. The texture reduces reflection losses at the front surface 114, thereby preferably improving the efficiency of the solar cell by raising its current. It is noted that the texture in the exposed rear-surface regions is not shown in FIG. 5. Following the texturing, the wafer 100 is cleaned using standard wet-chemical cleaning procedures.

As shown in FIG. 6, the wafer 100 is then diffused on both sides in a high-temperature diffusion furnace to form respective n+ layers 118, 120. In one embodiment, a liquid phosphorus source (POCl₃) is used. Alternatively, the wafer 100 can be diffused only on the rear surface 118 by front-to-front loading of wafers into the diffusion carriers. In this embodiment, the junction depth of the n+ diffusion 118, 120 is in the range of 0.5 to 1 μm and the sheet resistance in the range of 20 to 60 Ohm/square. The n+ layer 118 at the rear forms a so-called back surface field (BSF) layer, which advantageously improves both the recombination losses in the solar cell and the contact resistance losses.

Next, as shown in FIG. 7, a protective dielectric layer 122 is applied to the rear surface of the wafer 100. A subsequent etch-back solution (such as TMAH) is then used to etch-back the n+ layer 120 on the front-side. In one embodiment, the sheet resistance of the n-doped layer 120 on the front is preferably around 120-160 Ohm/square.

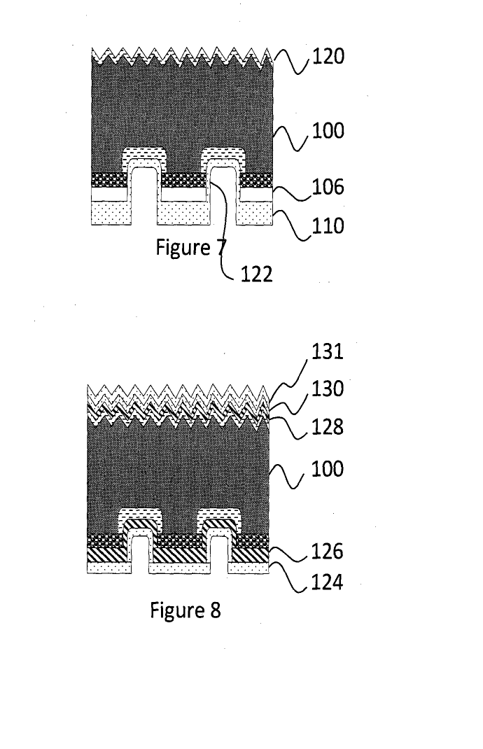

As shown in FIG. 8, the diffusion barrier layers (SiN 110 and SiO₂ 106, FIG. 7) are then removed using a hydrofluoric acid (HF) dip, and dielectric layers 124, 126, 128, 130 are applied to serve as antireflection coating (ARC) and surface passivation on the front surface 128, 130, 131 and for surface passivation at the rear surface 124, 126. In one embodiment, these dielectric layers are stacks of thermal silicon oxide (SiO₂) 126, 128 and amorphous PECVD silicon nitride (SiNₓ) 124, 130. Aluminium oxide (Al₂O₃), amorphous silicon (a-Si:H), or stacks of one or more of these materials may be used in different embodiments.

As shown in FIG. 9, the solar cell 132 is formed after screen-print metallisation e.g. forming contact bars 134, 136 of both n-doped and p-doped regions e.g. 135, 137 respectively. The metal pastes used in this embodiment are fritted glass-metal pastes, which preferably provide a good contact resistance by firing the pastes at high temperature through the dielectric surface passivation stack 138 [124, 126]. Typical firing temperatures are around 630-690° C.

The described embodiments advantageously provide large-area ABC cells with accurate alignment between the laser ablated diffused area and the screen printed metal. This is achieved in example embodiments by using two different alignment systems, one in the laser and one in the printer. As will be appreciated by a person skilled in the art, deviation from alignment between the contacts and the doped regions can result in performance deterioration of the solar cell.

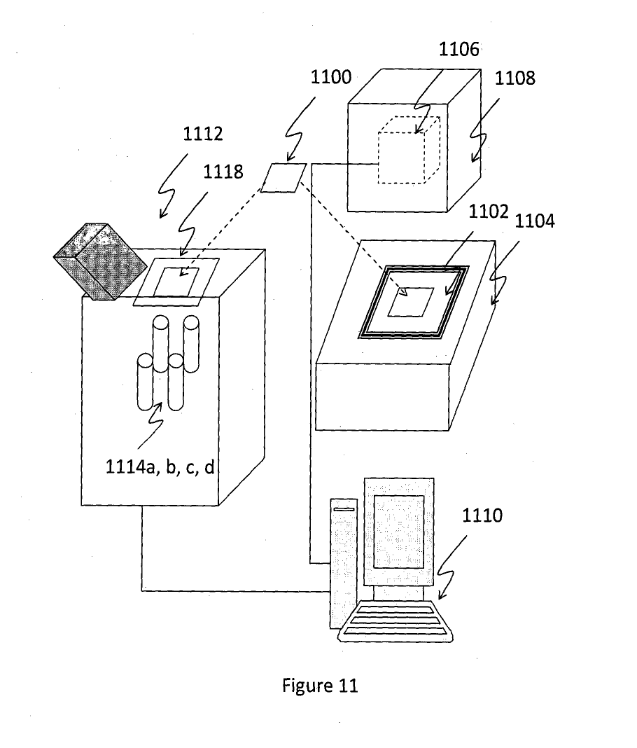

FIG. 11 shows a schematic drawing illustrating the alignment systems in the laser and printer respectively, configured to execute corresponding alignment processes, according to an example embodiment. A wafer 1100 is manually or automatically placed in a chuck 1102 of a laser stage 1104. A vision system 1106 in the laser system 1108 detects the wafer 1100 contour/edges. The angular offset values are recorded. A software algorithm stored and executed in the vision system 1106 calculates the centre of the wafer 1100 from the obtained images of the wafer 1100 edges. The pattern (e.g. in the form of an Autocad file) is then imported and a rotation correction (implemented as software algorithm stored and executed on a computer system 1110) is applied according to the detected angular deviation.

The screen printer 1112 has four cameras 1114 a-d to detect the four edges of the square (or pseudosquare) wafer 1100 and fiducial marks on the print screen 1118. The upward looking cameras 1114a-d see the wafer 1100 edges and the fiducial marks e.g. 1116 on the screen 1118. The relative position of these two features allows software stored and executed on the printer 1112 to make any necessary fine adjustments to the screen's 1118 position before the printing process takes place.

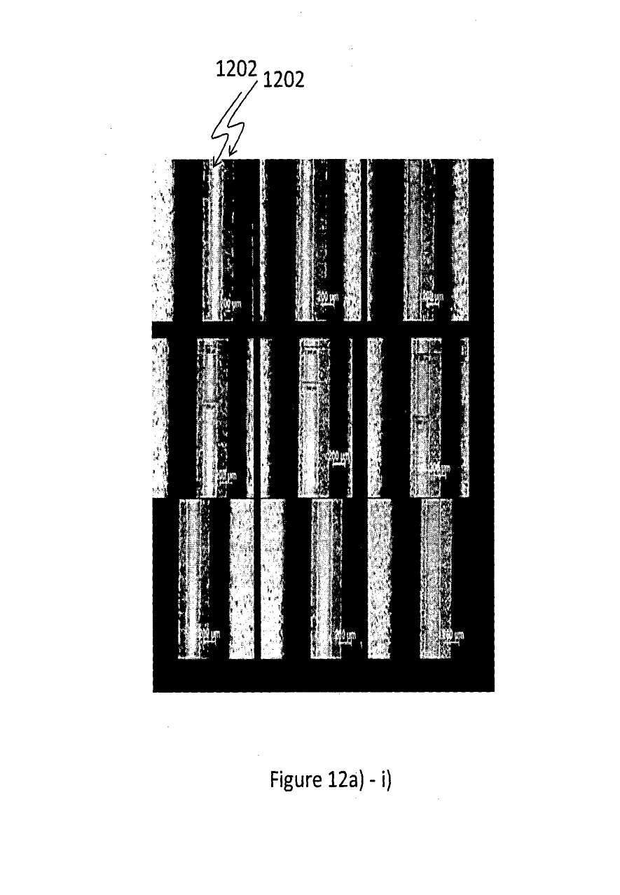

FIGS. 12 a)-i) show microscope images of approximately 200 μm wide screen printed metal fingers, e.g. 1202 on a 500 μm wide laser scribed line e.g. 1202, achieved using the laser and the screen printer set-up as described above with reference to FIG. 11.

The described embodiment, which utilises screen printing for the formation of the metal contacts of the all-back-contact silicon wafer solar cell, can advantageously be readily manufactured using processing techniques that are less expensive than micro-electronic circuit processing.

As described above, forming the interdigitated doped regions can be achieved by first applying one dopant type to the silicon wafer rear surface by means of diffusion, ion implantation, or laser doping in example embodiments. Then, a laser ablation of a masking layer followed by a subsequent etching step is used to form the oppositely-doped region by means of diffusion or laser doping in example embodiments.

By applying a dielectric stack at the rear surface, the rear surface advantageously becomes passivated. The front surface is passivated by dielectric materials, such a thermal silicon oxide (SiO₂), PECVD silicon nitride (SiN), aluminium oxide (Al₂O₃), amorphous silicon (a-Si:H), or stacks of one or more of these materials. A metal paste is preferably applied by screen-printing techniques and co-fired for both polarities through the rear dielectric stack. In a different embodiment, small line openings are fabricated using laser ablation techniques.

The front of the cell is preferably textured, as is the case for conventional silicon wafer solar cells. The dielectric stack at the front advantageously simultaneously provides surface passivation and anti-reflective properties.

In one alternate embodiment, the p+ and n+ doped regions are applied by ion implantation using e.g. carbon-fibre masks for patterning. Alternatively, solid or gaseous dopant sources can be used as diffusion sources for both p+ and n+ doping in different embodiments.

In another embodiment, the SiN 110 (FIG. 5) can be replaced by any etch-resistant dielectric film.

In another embodiment, the stack 138 (FIG. 8) can be replaced by stacks of Al₂O₃ and SiN act as surface passivating layer. Alternatively, amorphous silicon oxide (a-Si:H), Al₂O₃, SiO₂, SiN or stacks of one or more of those materials can be used.

In yet another embodiment, the polarity of the diffusions can be reversed when using a p-doped wafer/substrate.

In yet another embodiment, the n+ front-surface-field (FSF) 120 (FIG. 7) can be replaced by a p+ diffusion to create a floating p-n junction to provide good surface passivation of the silicon wafer surface; this can be applied by e.g. a single p+ diffusion to diffuse both sides of the wafer. Alternatively, the n+ front-surface-field (FSF) 120 (FIG. 7) can be eliminated, altogether or by using another technique, such as fixed charges in SiN or Al₂O₃, to create good surface passivation making the FSF obsolete, or by moving the texture etch step prior to the doping mask step.

In yet another embodiment, a liquid dopant source is applied via spray-on, roll-on, or spin-on to diffuse the n+ regions e.g. 137.

In yet another embodiment, the fritted glass-metal paste can be replaced by a non-fritted paste. In such embodiments, laser ablation can e.g. be applied to provide local openings in the dielectric surface passivation stack.

In yet another embodiment, a fritted glass-metal paste can be applied to print e.g. a 3-5 μm seed layer only to make good contact resistance. On top of the seed layer (after firing) a non-fritted metal paste can be printed by screen-printing methods or inkjet-printing methods to increase the thickness of the seed layer.

In yet another embodiment, laser doping can be used to form a heavier diffusion in the emitter (selective emitter; this provides the possibility to diffuse in the range of 100 Ohm/sq and use the selective emitter to dope in the range of 5-40 Ohm/sq to improve the contact resistance of the screen printed metal contact) and to reduce recombination losses. The laser doping can be applied by using the BSG (borosilicate glass) n+ layer 102 (FIG. 2) formed during the boron diffusion. Alternatively, the selective emitter can be formed at a later stage by applying a liquid dopant source via spray-on, roll-on, or spin-on to laser dope the p⁺ regions e.g. 135 to form p++ selective-emitter lines 1002. The resulting final structure 1004 is shown in FIG. 10.

In yet another embodiment, laser doping (laser chemical processing) can be used to form the heavy diffusion in the base contact e.g. 118 (FIG. 6) for selective BSF.

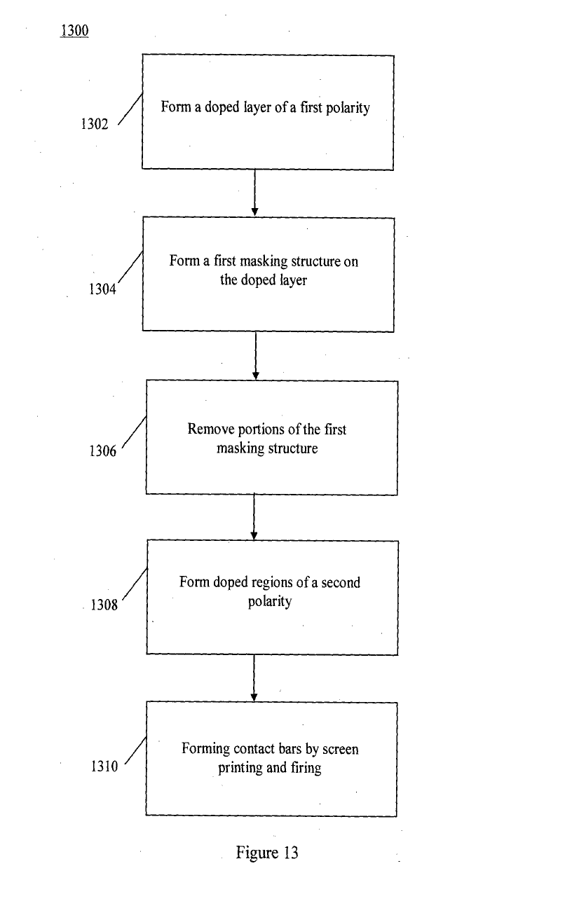

FIG. 13 shows a flow-chart 1300 illustrating a method of fabricating an ABC solar cell according to an example embodiment. At step 1302, a doped layer of a first polarity 102 is formed on a rear side of a wafer 100. At step 1304, a first masking structure 106, 110 is formed on the doped layer of the first polarity. At step 1306, portions of the first masking structure 106, 110 are removed using a first laser ablation process. At step 1308, doped regions of a second polarity 118, 135, 137 are formed in areas where the first masking structure has been removed. Finally, at step 1310, contact bars 134, 136 are formed by screen printing and firing such that each contact bar is in contact with one of the doped regions 135, 137.

The example embodiments described provide methods to manufacture all-back-contact silicon wafer solar cells that can be less complex and less costly than micro-electronic circuit processing while maintaining the high-efficiency potential of those structures, and can be particularly applied in the manufacturing of all-back-contact silicon wafer solar cells

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A method of fabricating an all-back-contact (ABC) solar cell comprising:
forming a doped layer of a first polarity on a rear side of a wafer;
forming a first masking structure on the doped layer of the first polarity;
removing portions of the first masking structure using a first laser ablation process;
forming doped regions of a second polarity in areas where the first masking structure has been removed; and
forming contact bars by screen printing and firing such that each contact bar is in contact with one of the doped regions.

2. The method as claimed in claim 1, further comprising applying a first alignment process for the first laser ablation process; and applying a second corresponding alignment process for the screen printing of the contact bars.

3. The method as claimed in claim 1, wherein forming the doped region of the second polarity comprises:
applying a caustic etch to expose deeper lying regions of the wafer in the openings formed in the first masking structure by the first laser ablation process, and
doping the exposed portions of the wafer.

4. The method as claimed in claim 1, further comprising forming a dielectric passivation structure over the entire rear surface of the wafer.

5. The method as claimed in claim 4, wherein forming the contact bars by screen printing comprises screen printing a fritted metal paste on the dielectric passivation structure and firing the fritted paste to form at least respective seed layers of the contact bars.

6. The method as claimed in claim 5, wherein the fritted metal paste is screen printed such that the contact bars are in contact with the silicon wafer after the firing process.

7. The method as claimed in claim 5, further comprising built-up of the contact bars from the seed layers using screen printing or ink-jet printing.

8. The method as claimed in claim 4, wherein forming the contact bars by screen printing comprises forming openings in the dielectric passivation structure and screen printing a non-fritted metal paste to form the contact bars.

9. The method as claimed in claim 8, wherein the openings in the dielectric passivation layer are formed by a second laser ablation process.

10. The method as claimed in claim 1, wherein forming the doped layer of the first polarity comprises using diffusion doping from a solid or gaseous source, or ion implantation.

11. The method as claimed in claim 1, wherein forming the doped regions of the second polarity comprises using diffusion doping from a solid or gaseous source, or ion implantation.

12. The method as claimed in claim 1, further comprising texturing a front surface of the wafer.

13. The method as claimed in claim 1, further comprising forming a dielectric structure on a front surface of the wafer.

14. The method as claimed in claim 13, wherein the dielectric structure has passivation and anti-reflective properties.

15. An all-back-contact (ABC) solar cell formed using the method as claimed in claim 1.

16. The solar cell as claimed in claim 15, further comprising a dielectric passivation structure over the entire rear surface of the wafer.

17. The solar cell as claimed in claim 15, further comprising a textured front surface of the wafer.

18. The solar cell as claimed in claim 15, further comprising a dielectric stack on a front surface of the wafer.

19. The solar cell as claimed in claim 18, wherein the dielectric stack has passivation and anti-reflective properties.
